(19) United States
(12) Patent Application Publication
(10) Pub. No.: US 2006/0042675 A1
(43) Pub. Date: Mar. 2, 2006

(54) Thermoelectric device and method of manufacturing the same

(75) Inventors: Kazuki Tateyama, Yokohama-shi (JP); Takahiro Sogou, Yokohama-shi (JP); Tomohiro Iguchi, Kawasaki-shi (JP); Hiroyoshi Hanada, Yokohama-shi (JP); Yasuhito Saito, Yokohama-shi (JP); Masayuki Arakawa, Yokohama-shi (JP); Naruhito Kondo, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/205,159

(22) Filed: Aug. 17, 2005

(30) Foreign Application Priority Data
Aug. 31, 2004 (JP) 2004-252838

(51) Int. Cl. H01L 35/30; H01L 35/28

(52) U.S. Cl. 136/212; 136/205

(57) ABSTRACT

In order to make a thermoelectric device usable in a high temperature environment of 300° C. or above, the necessity for solder is eliminated by bonding each electrode of a second substrate to one end of each thermoelectric element by using gold. Further, a conductive member, capable of accommodating expansion and contraction of the thermoelectric elements, is provided between each electrode of a first substrate, on which bonding by gold is not performed, and the other end of each thermoelectric element. Additionally, a lid is placed outside to the second substrate, and the lid and the first substrate are coupled so that pressure can be applied between the first and second substrates. Thus, the second substrate, the electrodes and the thermoelectric elements are held. This prevents the thermoelectric elements from being damaged due to thermal deformation as in the case where electrodes are bonded to thermoelectric elements by solder.

### CROSS-REFERENCE TO RELATED APPLICATIONS

This application is based upon and claims the benefit of priority from Japanese Patent Application No. 2004-252838 filed on Aug. 31, 2004; the entire contents of which are incorporated herein by reference.

### BACKGROUND OF THE INVENTION

1. Field of the Invention

The present invention relates to a thermoelectric device capable of performing conversion between heat and electricity.

2. Description of the Related Art

Thermoelectric devices are devices utilizing thermoelectric effects, such as the Thomson effect, the Peltier effect, and the Seebeck effect. As temperature regulation units which convert electricity into heat, thermoelectric devices have been already put into mass production. Further, also as electric power generation units which convert heat into electricity, thermoelectric devices are being researched and developed. In a thermoelectric device, a plurality of thermoelectric elements are arranged between two insulating substrates having electrodes so as to be connected in series electrically and in parallel thermally.

In order to bring the electric power generation efficiency of the thermoelectric device closer to those of the thermoelectric elements themselves, it is necessary that heat be supplied to one end of the thermoelectric elements and radiated from the other end thereof in an efficient manner. Accordingly, for each of the insulating substrates, a ceramic substrate which is excellent in heat conduction is used. Moreover, the electrodes placed at ends of the thermoelectric elements are made of a material having low electric resistance. The electrodes and the thermoelectric elements are bonded to each other by use of solder.

However, since the melting point of solder is approximately 150 to 300° C., the heat resistance of the thermoelectric device has to be approximately 150 to 300° C. The temperature range in which the device can be used is thus limited, and there has been a problem that the device cannot be used in a high temperature environment of 300° C. or more.

### SUMMARY OF THE INVENTION

An object of the present invention is to provide a thermoelectric device usable even in a high temperature environment of 300° C. or more and to provide a method of manufacturing the same.

A thermoelectric device according to a first aspect of the present invention includes: a first substrate and a second substrate each including a plurality of electrodes; and a plurality of thermoelectric elements placed between the first and second substrates, in a manner that one end and the other end of each of the thermoelectric elements correspond respectively to one of the electrodes of the first substrate and to one of the electrodes of the second substrate. Each of the electrodes of any one of the first and second substrates is bonded to one end of one of the thermoelectric elements corresponding to the electrode by use of gold.

In the present invention, the electrodes of any one of the first and second substrates and ends of the thermoelectric elements are bonded to each other by use of gold, the ends corresponding to the respective electrodes. This eliminates the necessity for solder and makes it possible to use the thermoelectric device until the melting point of gold is reached. Accordingly, the thermoelectric device can be used even in a high temperature environment of 300° C. or more, and the operating temperature range can be widened.

The thermoelectric device further includes a conductive member capable of accommodating expansion and contraction of the thermoelectric elements, and placed between each of the electrodes of one substrate different from the one that is bonded by the gold and one end of each of the thermoelectric elements corresponding to the electrode. The thermoelectric device further includes a lid placed outside to the second substrate and coupled to the first substrate so that pressure can be applied between the first and second substrates.

In the present invention, the conductive member capable of accommodating the expansion and contraction of the thermoelectric elements is provided between each of the electrodes of the substrate on which bonding using gold is not performed, and one end of one of the thermoelectric elements. Further, the lid is coupled to the first substrate so that pressure can be applied between the second and the first substrate, whereby the conductive member is held. Thus, the deformation and movement of the thermoelectric elements in a high-temperature state are accommodated by the conductive members. Accordingly, the thermoelectric elements and the like can be prevented from being damaged as compared with the case where the electrodes and ends of the thermoelectric elements are bonded to each other by use of solder.

In the thermoelectric device, the conductive member is placed between each of the electrodes of the first substrate and one end of each of the thermoelectric elements corresponding to the electrode.

In the present invention, by placing the conductive member between each of the electrodes of the first substrate and one end of one of the thermoelectric elements, in the case where heat is supplied to the second substrate through the lid, the elasticity of the conductive member can be successfully prevented from being deteriorated as compared with the case where the conductive member is placed between each electrodes of the second substrate and one of the thermoelectric elements. This is because the first substrate acts as a radiator plate and is at a lower temperature than the second substrate.

In the thermoelectric device, a portion formed by extending an edge of the lid is coupled to the first substrate.

In the present invention, coupling the portion formed by extending the edge of the lid to the first substrate eliminates the necessity of additionally providing a coupling member for coupling the lid and the first substrate. Thus, the manufacturing process can be simplified, and the manufacturing cost can be reduced.

In the thermoelectric device, the conductive member is welded to each of the electrodes at two or more positions per electrode.

In the present invention, by welding the conductive member at two or more positions per electrode, the movement of the conductive member is reduced as compared with the case where the conductive member is merely brought into contact with the electrode. Thus, stability of the device is improved, and variations in performance among the devices can be prevented.

In the thermoelectric device, the positions at which the conductive member is welded are positions on the electrodes, the positions different from portions in which the thermoelectric elements are placed.

In the present invention, the conductive member is welded at positions on each of the electrodes, the positions corresponding to portions in which the thermoelectric elements are not placed. This prevents thermal efficiency from being decreased by a reduction of the contact areas between the thermoelectric elements and the conductive member, the reduction otherwise resulting from the deformation of the shapes of the welded portions.

A thermoelectric device manufacturing method according to a second aspect of the present invention includes the steps of: placing gold on one end of each of a plurality of thermoelectric elements; placing gold on a plurality of electrodes of any one of a first substrate and a second substrate; bonding the gold on the thermoelectric elements and the gold on the electrodes of the foregoing substrate; and placing the substrate having the thermoelectric elements bonded thereto and other substrate so that the substrates may face each other with the thermoelectric elements interposed therebetween.

In the present invention, since gold is placed on one end of each of the plurality of thermoelectric elements and gold is also placed on the plurality of electrodes, solid state diffusion bonding of gold to gold can be performed.

It is desirable that the thermoelectric device manufacturing method further include the steps of: placing a conductive member capable of accommodating expansion and contraction of the thermoelectric elements between each electrode of one substrate different from the one that is bonded by the gold and one end of one of the thermoelectric elements corresponding to the electrode; and placing a lid outside to the second substrate, and coupling the lid to the first substrate so that pressure is applied between the first and second substrates.

In the step of coupling the lid to the first substrate, it is desirable that a coupling portion of the lid is welded to a welding metal pattern placed to surround all of the electrodes on the first substrate with a metal foil.

In the step of placing the conductive member, it is desirable that the conductive member be welded to each of the electrode at two or more positions per electrode. It is desirable that the positions at which the conductive member be welded are positions on the electrodes, the positions different from portions in which the thermoelectric elements are placed.

### BRIEF DESCRIPTION OF THE DRAWINGS

FIG. 1 is a cross-sectional view showing a constitution of a thermoelectric device in one embodiment.

FIG. 2 is a plan view showing electrodes and a welding metal pattern on a first substrate.

FIG. 3 is a plan view showing the positions on one electrode at which the resistance welding of a conductive member is performed.

FIG. 4 is a view showing a first step in manufacture of the thermoelectric device.

FIG. 5 is a view showing a second step in the manufacture of the thermoelectric device.

FIG. 6 is a view showing a third step in the manufacture of the thermoelectric device.

FIG. 7 is a view showing a fourth step in the manufacture of the thermoelectric device.

FIG. 8 is a view showing a fifth step in the manufacture of the thermoelectric device.

FIG. 9 is a view showing a sixth step in the manufacture of the thermoelectric device.

FIG. 10 is a view showing the seventh step in the manufacture of the thermoelectric device.

FIG. 11 is a cross-sectional view showing the constitution of a thermoelectric device in another embodiment.

### DESCRIPTION OF THE EMBODIMENT

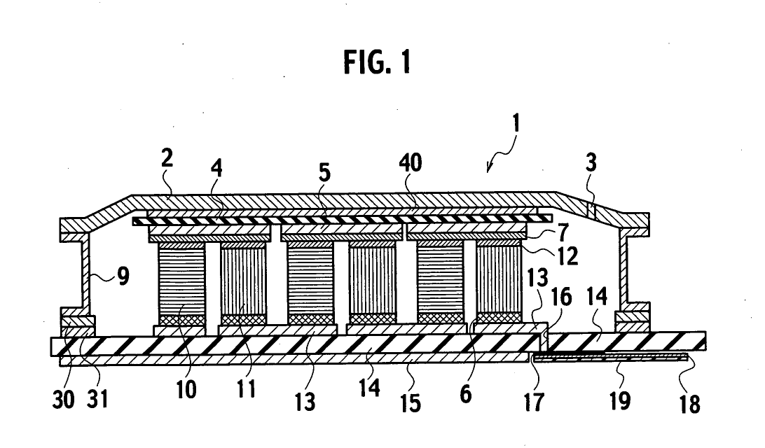

As shown in the cross-sectional view of FIG. 1, a thermoelectric device 1 of this embodiment has a first substrate 14 including a plurality of electrodes 13, a second substrate 4 including a plurality of electrodes 5, and a plurality of p-type thermoelectric elements 10 and a plurality of n-type thermoelectric elements 11 placed between these substrates. Each thermoelectric element 10 or 11 is placed so that one end thereof may correspond to an electrode 13 of the first substrate 14 and that the other end thereof may correspond to an electrode 5 of the second substrate 4. Electrodes 5 and 13 are arranged so that all of the thermoelectric elements 10 and 11 can be connected in series electrically. Further, the thermoelectric elements 10 and 11 are arranged in parallel thermally.

A surface of each electrode of the first substrates 14 or second substrates 4, one end of each thermoelectric element 10, and one end of each thermoelectric element 11 are plated with gold. In this embodiments, as one example, gold 7 is placed on the surface of each electrode 5 of the second substrate 4, and gold 12 is placed on the one end of each thermoelectric element 10, and the one end of each thermoelectric element 11. Further, the gold 7 on the electrodes 5 and the gold 12 on the thermoelectric elements 10 and 11 are bonded to each other by solid state diffusion.

Thus, in the thermoelectric device 1, the necessity for solder is eliminated by bonding the electrodes and the thermoelectric elements to each other by use of gold. Incidentally, as the gold used here, other than pure gold, gold having impurities mixed therein or gold alloy may be used.

Conductive members 6 capable of accommodating expansion and contraction of the thermoelectric elements 10 and 11 are placed between the electrodes 13 on the first substrate 14, on which bonding using gold is not performed, and ends of the thermoelectric elements 10 and 11, the ends being at positions corresponding to the electrodes 13. As these conductive members 6, for example, used are metal pieces obtained by knitting metal fibers into meshes so that deformation in the thickness direction is allowed. Note that this deformation may be any of elastic deformation and plastic deformation.

Moreover, a lid 2 placed outside to the second substrate 4 so as to cover the second substrate 4 is coupled to the first substrate 14 by a coupling member 9 so that pressure can be applied between the second substrate 4 and the first substrate 14. Thus, the lid 2 and the first substrate 14 are placed to face each other with the thermoelectric elements 10 and 11 interposed therebetween. Further, the second substrate 4, the electrodes 5 on the second substrate 4, and the conductive members 6 are held in the state where pressure is applied by the lid 2 and the first substrate 14 in a longitudinal direction of the thermoelectric elements 10 and 11, i.e., in a direction in which a current flows with the generation of an electromotive force.

In this thermoelectric device 1, the conductive members 6 are not fixed to the thermoelectric elements 10 and 11 but merely brought into contact therewith. Thereby, the movement and deformation of the thermoelectric elements 10 and 11 are accommodated by the conductive members 6 even in a case where, when the device is operated in a high temperature environment, the amount of deformation of each component differs from each other because of differences in linear expansion coefficients among the components or because of a difference in temperature between a heat absorption side and a heat radiation side. Thus, the bonding portions of the thermoelectric elements 10 and 11 and the thermoelectric elements themselves are prevented from being damaged. Further, since variations in height among the thermoelectric elements 10 and 11 are also accommodated by the conductive members 6, a step for selection, inspection, or the like according to height can be eliminated.

The thermoelectric device 1 can convert heat supplied to the lid 2 into electricity by use of the thermoelectric elements 10 and 11. By forming a metal film 40 between the lid 2 and the second substrate 4, heat absorption efficiency of the device is increased.

Further, the conductive members 6 are placed, not between the electrodes 5 of the second substrate 4 of a high temperature side to which heat is supplied and the thermoelectric elements 10 and 11, but between the electrodes 13 of the first substrate 14 of a heat-radiating low temperature side and the thermoelectric elements 10 and 11, whereby the deterioration of the elasticity of the conductive members 6 in a high temperature environment is reduced.

The lid 2 and the first substrate 14 are coupled to each other by use of a coupling member 9. The coupling member 9 is welded to a welding metal pattern 31 on the first substrate 14 with metal foil 30 interposed therebetween. This eliminates the necessity of brazing to the first substrate 14 a portion of the lid 2 which is to be coupled to the first substrate 14, and prevents the brazed portion from being damaged at the time of cooling after brazing at 900° C. in the manufacturing process.

The thermoelectric device 1 is a box structure sealed with the lid 2, the first substrate 14, and the coupling member 9. The inside of the box structure is set to be a reduced-pressure atmosphere so that the deformation or destruction of the structure does not easily occur even if the structure suffers a large temperature change. In order to maintain this atmosphere, the box structure is hermetically sealed.

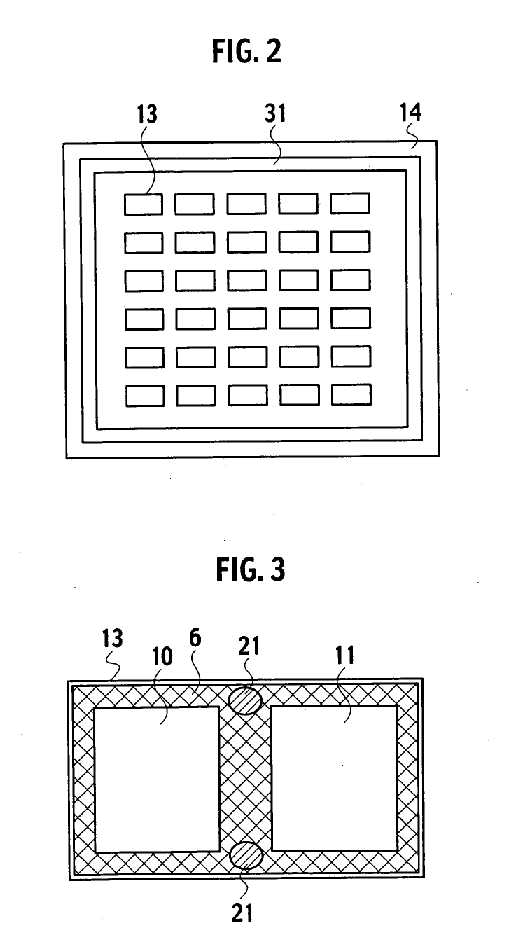

As shown in the plan view of FIG. 2, the welding metal pattern 31 is placed so as to surround all of the electrodes 13 on the first substrate 14. The coupling member 9 has a shape corresponding to this metal pattern 31 and surrounding all thermoelectric elements 10 and 11, and acts as a frame of the box structure.

As shown in the plan view of FIG. 3, the conductive members 6 are fixed to the electrodes 13 by resistance welding at two or more positions for each electrode 13. By doing so, the movement of the conductive members is reduced as compared with the case where the conductive members 6 are merely brought into contact with the electrodes 13. Thus, stability of the device is improved, and variations in performance among the devices are prevented.

Further, the positions at which each conductive member 6 is fixed by resistance welding are set to be positions different from the portions on one electrode 13 in which the thermoelectric elements 10 and 11 are placed. It is particularly desirable that, as shown in FIG. 3, resistance welding be performed at two positions which are in a space between the thermoelectric elements 10 and 11, a segment connecting the two positions is orthogonal to the direction along which the thermoelectric elements 10 and 11 are arranged. This prevents thermal efficiency from being decreased by a reduction of the contact area between a thermoelectric element and a conductive member, the reduction otherwise resulting from the deformation of the shape of the conductive member caused by resistance welding.

An electromotive force generated in the thermoelectric elements 10 and 11 is extracted to the outside by way of a through hole 16 formed in the first substrate 14. As shown in FIG. 1, the electrodes 13 electrically connected to the thermoelectric elements 10 and 11 are exposed to the outside of the first substrate 14 through the through hole 16. The exposed portion is connected by use of solder to a metal interconnection 18 on a surface of an insulating resin 19 placed outside the first substrate 14. Thus, the airtightness of the thermoelectric device is improved by implementing an interconnection extended from electrodes of the thermoelectric device 1 through the through hole 16. Further, a metal film 15 is formed on the outer surface of the first substrate 14, thus improving heat radiation.

In the thermoelectric device 1, the voltage of an electromotive force is increased by electrically connecting the p-type thermoelectric elements 10 and the n-type thermoelectric elements 11 in series by use of the electrodes 13 of the first substrate 14 and the electrodes 5 of the second substrate 4. That is, a current flowing through the thermoelectric elements is extracted from the metal interconnection 18 after alternately passing through the p-type thermoelectric elements 10 and the n-type thermoelectric elements 11.

Incidentally, in this embodiment, the p type and the n type of the thermoelectric elements mean thermoelectric elements which are configured so that the respective directions of the current flows therein when heat is applied to ends of the thermoelectric elements may become opposite.

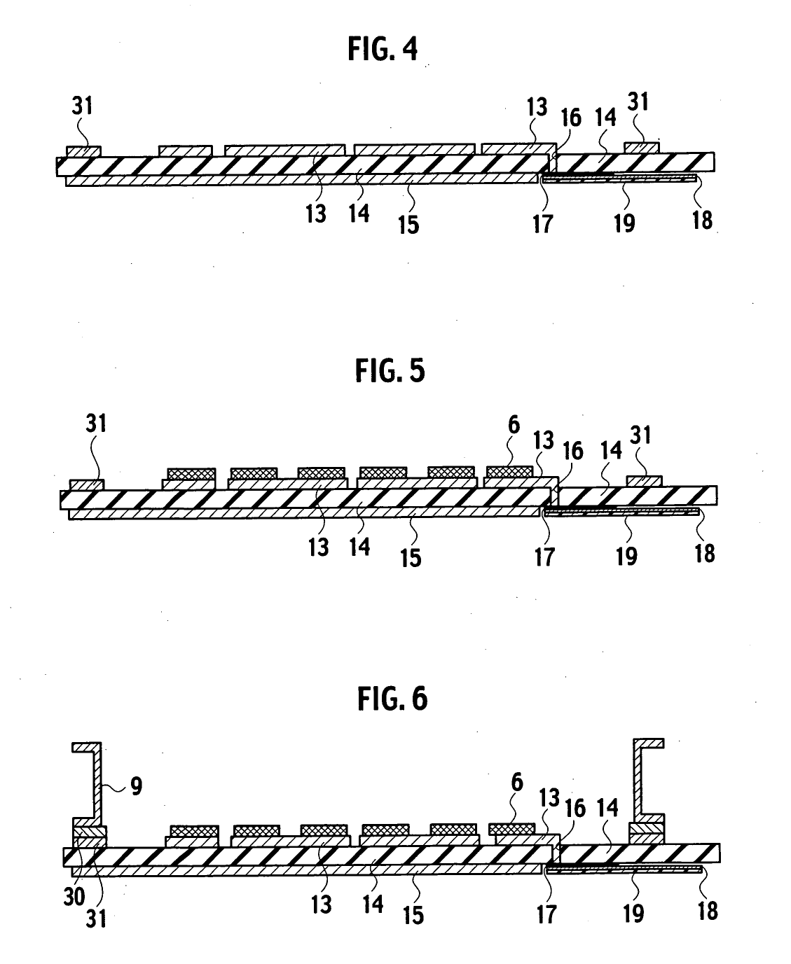

Next, one example of a process of manufacturing the thermoelectric device 1 will be described. First, as shown in the process drawing of FIG. 4, the plurality of electrodes 13 and the welding metal pattern 31 which surrounds all of the electrodes 13 are formed on the first substrate 14. Then, the metal film 15 is formed on the surface of the first substrate 14, the surface being opposite from the one having the electrodes 13 thereon. Further, the insulating resin 19 having the metal interconnection 18 formed on a surface thereof is placed on the outer surface of the first substrate 14, the outer surface being opposite from the surface where the electrodes 13 are provided, and the electrodes 13 are connected to the metal interconnection 18 through the through hole 16 provided in the first substrate 14. In this embodiment, as one example, Si₃N₄-based ceramic and copper are used for the first substrate 14 and the electrodes 13, respectively.

Subsequently, as shown in the process drawing of FIG. 5, the conductive members 6 are fixed to the electrodes 13 by resistance welding. The resistance welding of the conductive members 6 is performed at two or more positions for each electrode 13. As the conductive members 6, substances obtained by knitting copper wires having diameters of 0.6 mm into meshes are used.

Then, as shown in the process drawing of FIG. 6, the coupling member 9 is welded to the welding metal pattern 31 with the metal foil 30 interposed therebetween. This welding is laser welding or resistance welding. The coupling member 9 has a shape surrounding all electrodes in correspondence to the metal pattern 31. As the material of the coupling member 9, for example, Kovar is used. As the metal foil 30, nickel is used.

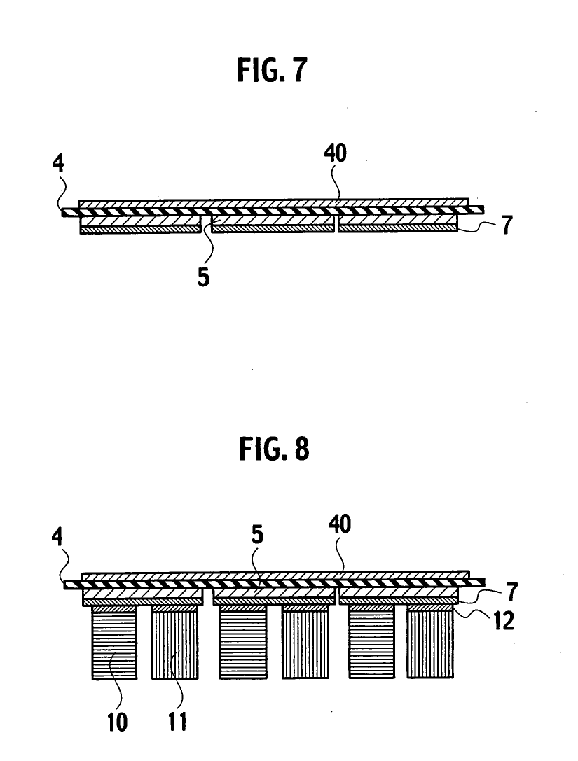

Next, as shown in FIG. 7, the second substrate 4 having the plurality of electrodes 5 formed on a plane surface thereof is prepared. The gold 7 is placed on a surface of each electrode 5 of the second substrate. The metal film 40 is formed on a surface of the second substrate 4, the surface being opposite from the one having the electrodes 5 provided thereon.

Subsequently, as shown in FIG. 8, the gold 12 is placed on one end of each thermoelectric element 10 and one end of each thermoelectric element 11. Further, this gold 12 and the gold 7 on the electrodes 5 of the second substrate 4 are bonded to each other by solid state diffusion. For this bonding, ultrasonic waves are used.

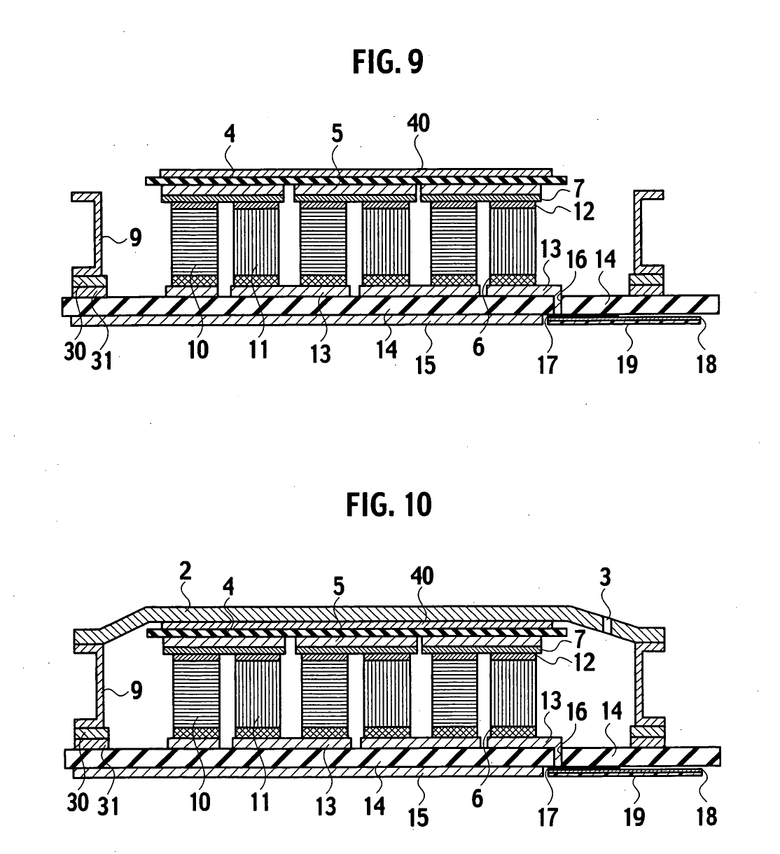

Then, as shown in FIG. 9, the second substrate 4 having the thermoelectric elements 10 and 11 bonded to the electrodes 5, and the first substrate 14 having the conductive members 6 fixed to the electrodes 13, are placed to face each other so that the thermoelectric elements 10 and 11 can be interposed therebetween.

Next, as shown in FIG. 10, the lid 2 in which a sealing hole 3 providing communication between the front and back sides thereof is provided is placed outside to the second substrate 4 so as to cover the second substrate 4. Further, the lid 2 and the coupling member 9 are welded to each other so that pressure can be applied between the lid 2 and the first substrate. As the material of the lid 2, SUS304 is used.

Finally, the thermoelectric device is left in a reduced-pressure atmosphere, and the sealing hole 3 is melted by a laser to be closed, whereby the thermoelectric device 1 having a hermetically sealed structure is obtained.

Thus, according to this embodiment, the electrodes 5 of the second substrate 4 and corresponding ends of the thermoelectric elements 10 and 11 are bonded to each other by use of gold. This eliminates the necessity for solder and makes it possible to use the thermoelectric device until the melting point of gold is reached. Accordingly, the operating temperature range can be widened.

According to this embodiment, the deformation and movement of the thermoelectric elements 10 and 11 are accommodated by the conductive members 6 by: providing the conductive members 6 capable of accommodating the expansion and contraction of the thermoelectric elements 10 and 11 between the electrodes 13 of the first substrate 14, on which bonding using gold is not performed, and the thermoelectric elements 10 and 11; and having the conductive members 6 being held by coupling the lid 2 to the first substrate 14 so that pressure can be applied between the lid 2 and the first substrate 14. Accordingly, the thermoelectric elements and the like can be successfully prevented from being damaged as compared with the case where the electrodes 13 and ends of the thermoelectric elements 10 and 11 are bonded to each other by use of solder.

According to this embodiment, the conductive members 6 are placed between the electrodes 13 of the first substrate 14 and ends of the thermoelectric elements 10 and 11. Accordingly, when heat is supplied to the second substrate 4 through the lid 2, the elasticity of the conductive members 6 can be successfully prevented from being deteriorated as compared with the case where the conductive members 6 are placed between the second substrate 4, which is the high temperature side, and the thermoelectric elements. This is because the first substrate 14 acts as a radiator plate and is at a lower temperature than the second substrate 4.

According to this embodiment, a coupling portion of the lid 2 which is to be coupled to the first substrate 14 is welded, with the metal foil 30 interposed therebetween, to the welding metal pattern 31 which is placed so as to surround all of the electrodes 13 on the first substrate 14. By doing so, the necessity of brazing this coupling portion to the first substrate 14 is eliminated, and the brazed portion can be prevented from being damaged at the time of cooling after brazing at 900° C. in the manufacturing process. This improves the reliability of the first substrate 14. Consequently, the reliability of the completed thermoelectric device can be improved.

According to this embodiment, the conductive members 6 are welded to the electrodes 13 at two or more positions for each electrode 13. By doing so, the movement of the conductive members 6 is reduced as compared with the case where the conductive members 6 are merely brought into contact with the electrodes 13. Accordingly, stability of the device is improved, and variations in performance among the devices can be prevented.

According to this embodiment, the conductive members 6 are welded at positions different from to the portions on the electrodes 13 in which the thermoelectric elements 10 and 11 are placed. This prevents thermal efficiency from being decreased by a reduction of the contact areas between the thermoelectric elements 10 and 11 and the conductive members 6, the reduction otherwise resulting from the deformation of the shape of the welded portions.

Incidentally, in this embodiment, SUS304 is used as the material of the lid 2, nickel is used for the metal foil 30, and copper is used for the electrodes 13 of the first substrate 14. However, these materials are not particularly limited as long as the effects of this thermoelectric device, such as the airtightness of the welded portion and the processability of the lid 2, can be obtained. Further, the metal foil 30 may be omitted as long as the airtightness of the welded portion can be obtained. Moreover, each welding method is not particularly limited to laser welding or resistance welding as long as the effects of the present invention can be obtained.

Further, in this embodiment, the electrodes 5 on the second substrate 4 and the thermoelectric elements 10 and 11 are bonded to each other by use of gold, and then the conductive members 6 are placed between the electrodes 13 on the first substrate 14 and the thermoelectric elements 10 and 11. However, in contrast to this, it is acceptable to bond the electrodes 13 on the first substrate 14 and the thermoelectric elements 10 and 11 by use of gold and then to place the conductive members 6 between the electrodes 5 on the second substrate 4 and the thermoelectric elements 10 and 11.

Furthermore, in this embodiment, the portion with which the lid 2 is to coupled to the first substrate 14 is welded to the welding metal pattern 31 with the metal foil 30 interposed therebetween. However, this is not limited to the metal foil 30. For example, the top of the metal pattern 31 may be plated with a brazing material instead of the metal foil 30.

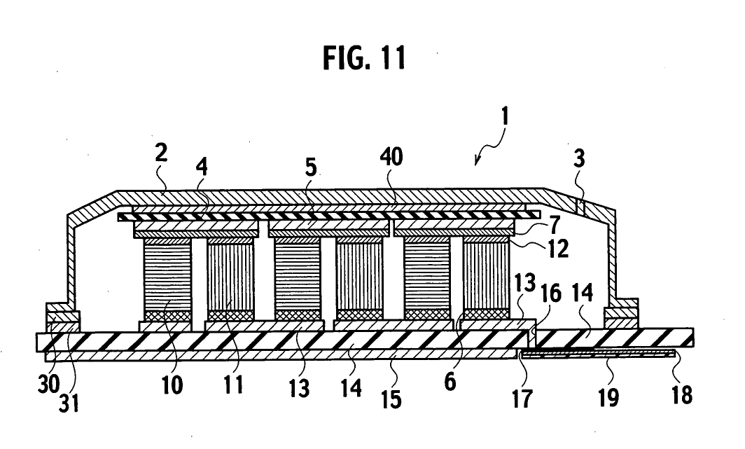

Next, a thermoelectric device in another embodiment will be described. As shown in the cross-sectional view of FIG. 11, this thermoelectric device has a constitution in which a portion formed by extending the edge of the lid 2 is coupled to the first substrate 14. That is, the lid 2 and a coupling member are integrally formed of the same member. As the material of the lid 2 and the portion formed by extending the lid, one or more metals such as SUS or Kovar are used. As for the coupling method, the portion formed by extending the lid 2 is welded by laser welding or resistance welding to the welding metal pattern 31 which is placed on a surface of the first substrate 14. Other than these, the same components as those of the thermoelectric device described using FIGS. 1 to 3 are denoted by the same reference numerals, and will not be further described here. Further, a method of manufacturing this thermoelectric device is also basically the same as the manufacturing method described using FIGS. 4 to 10, and will not be further described here.

According to this embodiment, coupling the portion formed by extending the edge of the lid 2 to the first substrate 14 eliminates the necessity of additionally providing a coupling member for coupling the lid 2 and the first substrate 14. Thus, the manufacturing process can be simplified, and the manufacturing cost can be reduced.

Incidentally, in each of the above-described embodiments, a description has been given by taking as an example a thermoelectric device which converts heat supplied to the lid 2 into electricity. However, the present invention can also be applied to a thermoelectric device which converts electricity into heat.

What is claimed is:

1. A thermoelectric device comprising:
a first substrate and a second substrate, each including a plurality of electrodes; and
a plurality of thermoelectric elements placed between the first and second substrates in a manner that one end and the other end of each of the thermoelectric elements correspond respectively to one of the electrodes of the first substrate and to one of the electrodes of the second substrate,
wherein each of the electrodes of any one of the first and second substrates is bonded to one end of one of the thermoelectric elements corresponding to the electrode by use of gold.

2. The thermoelectric device of claim 1, further comprising:
a conductive member capable of accommodating expansion and contraction of the thermoelectric elements, the conductive member being placed between each of the electrodes of one substrate different from the one that is bonded by the gold and one end of each of the thermoelectric elements corresponding to the electrode;
a lid placed outside to the second substrate, and coupled to the first substrate so that pressure can be applied between the first and second substrates.

3. The thermoelectric device of claim 2, wherein the conductive member is placed between each of the electrodes of the first substrate and one end of each of the thermoelectric elements corresponding to the electrode.

4. The thermoelectric device of claim 2, wherein the lid is coupled to the first substrate by way of a portion formed by extending an edge of the lid.

5. The thermoelectric device of claim 2, wherein the conductive member is welded to each of the electrodes at least two positions per electrode.

6. The thermoelectric device of claim 5, wherein the positions at which the conductive member is welded are positions on each of the electrodes, the positions different from those corresponding to portions in which the thermoelectric elements are placed.

7. A method of manufacturing a thermoelectric device, comprising the steps of:
placing gold on one end of each of a plurality of thermoelectric elements;
placing gold on a plurality of electrodes of any one substrate of a first and a second substrates;
bonding the gold placed on the thermoelectric elements to the gold placed on the substrate; and
placing the substrate having the thermoelectric elements bonded thereto and the other substrate so that the substrates may face each other with the thermoelectric elements interposed therebetween.

8. The method of manufacturing a thermoelectric device of claim 7, further comprising the steps of:
placing a conductive member, capable of accommodating expansion and contraction of the thermoelectric elements, between each electrode of one substrate different from the one that is bonded by the gold and one end of one of the thermoelectric elements corresponding to the electrode;
placing a lid outside to the second substrate, and coupling the lid to the first substrate so that pressure can be applied between the first and second substrates.

9. The method of manufacturing a thermoelectric device of claim 8, wherein, in the step of coupling the lid to the first substrate, a coupling portion of the lid is welded to a welding metal pattern placed to surround all of the electrodes on the first substrate with a metal foil.

10. The method of manufacturing a thermoelectric device of claim 8, wherein, in the step of placing the conductive member, the conductive member is welded to each of the electrodes at least two positions per electrode.

11. The method of manufacturing a thermoelectric device of claim 10, wherein the positions at which the conductive member is welded are positions on each of the electrodes, the positions different from those corresponding to portions in which the thermoelectric elements are placed.
